(19) United States
(12) Patent Application Publication
(10) Pub. No.: US 2025/0081571 A1
(43) Pub. Date: Mar. 6, 2025

(54) MULTI-CHANNEL STACK NANOWIRE

(71) Applicant: International Business Machines Corporation, Armonk, NY (US)

(72) Inventors: Effendi Leobandung, Stormville, NY (US); Tze-Chiang Chen, Yorktown Heights, NY (US)

(21) Appl. No.: 18/238,594

(22) Filed: Aug. 28, 2023

(51) Int. Cl. H01L 29/66; H01L 27/092; H01L 29/06; H01L 29/423; H01L 29/775; H01L 29/786

(52) U.S. Cl. CPC H10D 64/018; H10D 30/014; H10D 30/031; H10D 30/43; H10D 30/6757; H10D 62/116; H10D 62/121; H10D 84/85; H10D 30/6735

(57) ABSTRACT

A semiconductor structure includes a plurality of gate-all-around field effect transistors, each of the gate-all-around field effect transistors including: first and second source-drain regions; a plurality of nanowire channels interconnecting the first and second source-drain regions; and a common gate. The common gate includes an upper gate portion above the plurality of nanowire channels and a lower gate portion surrounding the plurality of nanowire channels. A unitary spacer structure includes an upper spacer portion between the upper gate portion and the first and second source-drain regions and a lower spacer portion between the lower gate portion and first and second source-drain regions. The upper spacer portion and the lower spacer portion have aligned left and right edges.

### BACKGROUND

The present invention relates generally to the electrical, electronic and computer arts and, more particularly, to techniques for multi-channel stack nanowire field effect transistors (FETs) and the like.

In nanowire transistors, the transistor channel is made up of an array of nanowires (diameter on the order of a few nanometers), with the gate surrounding the nanowires (gate all around or GAA). In nanosheet transistors, the transistor channel is made up of an array of nanosheets (thickness on the order of a few nanometers), with the gate surrounding the nanosheets (also GAA). Nanowire and nanosheet transistors can generally be configured as n-type field effect transistors (NFETs), p-type field effect transistors (PFETs), or as complementary metal oxide semiconductor (CMOS) structures (including both NFETs and PFETs).

However, continued scaling of nanowire and nanosheet FETs has been limited by short channel effects, parasitic capacitance effects, and the like.

### BRIEF SUMMARY

Principles of the invention provide techniques for a multi-channel stack nanowire. In one aspect, an exemplary semiconductor structure includes a plurality of gate-all-around field effect transistors, each of the gate-all-around field effect transistors including: first and second source-drain regions; a plurality of nanowire channels interconnecting the first and second source-drain regions; a common gate, the common gate including an upper gate portion above the plurality of nanowire channels and a lower gate portion surrounding the plurality of nanowire channels; and a unitary spacer structure including an upper spacer portion between the upper gate portion and the first and second source-drain regions and a lower spacer portion between the lower gate portion and first and second source-drain regions. The upper spacer portion and the lower spacer portion have aligned left and right edges.

Optionally, the lower gate portion has a lower gate portion width; the upper gate portion has an upper gate portion width; and the upper gate portion width is greater than the lower gate portion width.

Optionally, the lower spacer portion has a lower spacer width; the upper spacer portion has an upper spacer width; and the upper spacer width is less than the lower spacer width.

Optionally, the semiconductor further includes a substrate; the gate-all-around field effect transistors are formed on the substrate; and the lower spacer portion includes an underlying portion between the lower gate portion and the substrate.

In another aspect, another exemplary semiconductor structure includes a plurality of gate-all-around field effect transistors, each of the gate-all-around field effect transistors including: first and second source-drain regions; a plurality of nanowire channels interconnecting the first and second source-drain regions; a common gate, the common gate including an upper gate portion above the plurality of nanowire channels and a lower gate portion surrounding the plurality of nanowire channels, the lower gate portion having a lower gate portion width, the upper gate portion having an upper gate portion width greater than the lower gate portion width; and a unitary spacer structure including an upper spacer between the upper gate portion and the first and second source-drain regions and a lower spacer between the lower gate portion and first and second source-drain regions. The lower spacer has a lower spacer width, and the upper spacer has an upper spacer width less than the lower spacer width.

Optionally, the semiconductor further includes a substrate; the gate-all-around field effect transistors are formed on the substrate; and the lower spacer portion includes an underlying portion between the lower gate portion and the substrate.

In still a further aspect, an exemplary method of forming a semiconductor structure includes providing a starting structure. The starting structure includes a substrate, the substrate having a plurality of shallow trench isolation regions formed therein; a plurality of fin stacks, each of the fin stacks including a high SiGe layer located outward of the substrate, a plurality of alternating low SiGe sacrificial layers and silicon channels outward of the high SiGe layer, and hard mask oxide patterned into nanowire bumps located outward of an outermost one of the silicon channels, the fin stacks having cavities etched therein such that the silicon channels define nanowires with a generally square cross section; and dummy gate stacks above the substrate and perpendicular to the fin stacks. Additional steps include carrying out angled ion implantation to damage the low SiGe sacrificial layers; carrying out selective etching to remove all high SiGe layer and part of the alternating low SiGe sacrificial layers damaged by the angled ion implantation; depositing insulator material between the dummy gate stacks and into the regions vacated by the removed high SiGe layer and removed part of the alternating low SiGe sacrificial layers, and etching the deposited insulator material to form a unified spacer structure covering sides of the dummy gate stacks and the regions vacated by the removed high SiGe layer and the removed part of the alternating low SiGe sacrificial layers; epitaxially growing source-drain regions between the gate stacks; and forming replacement metal gates between the source-drain regions, to replace the dummy gate stacks.

Optionally, the step of depositing and etching the insulator material includes forming the unified spacer structure to include an upper spacer portion between the dummy gate stacks and the first and second source-drain regions and a lower spacer portion between remaining parts of the alternating low SiGe sacrificial layers and first and second source-drain regions, and the lower spacer portion includes an underlying portion between an innermost one of the remaining parts of the alternating low SiGe sacrificial layers and the substrate

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
Allow further scaling of semiconductor circuits using GAA nanowire field effect transistors;
Reduced short channel effects in semiconductor circuits using GAA nanowire field effect transistors;
Reduced parasitic capacitance and resistance in semiconductor circuits using GAA nanowire field effect transistors.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 is a starting structure for forming multi-channel stack nanowire FETs, according to aspects of the invention;

FIG. 2 is a top view of the structure of FIG. 1 after channel patterning and deposition of shallow trench isolation (STI), according to aspects of the invention;

FIG. 3A is a cross section taken along line A in FIG. 2, according to aspects of the invention;

FIG. 3B is a cross section taken along line C in FIG. 2, according to aspects of the invention;

FIG. 4 is a top view of the structure of FIGS. 2, 3A, and 3B after patterning of a nanowire hard mask, according to aspects of the invention;

FIG. 5A is a cross section taken along line B in FIG. 4, according to aspects of the invention;

FIG. 5B is a cross section taken along line A in FIG. 4, according to aspects of the invention;

FIG. 5C is a cross section taken along line C in FIG. 4, according to aspects of the invention;

FIG. 6 is a top view of the structure of FIGS. 4, and 5A-5C after patterning of dummy gates, according to aspects of the invention;

FIG. 7A is a cross section taken along line B in FIG. 6, according to aspects of the invention;

FIG. 7B is a cross section taken along line A in FIG. 6, according to aspects of the invention;

FIG. 7C is a cross section taken along line C in FIG. 6, according to aspects of the invention;

FIG. 8 is a top view of the structure of FIGS. 6, and 7A-7C after etching fins on source drain regions with fin hard mask, according to aspects of the invention;

FIG. 9A is a cross section taken along line B in FIG. 8, according to aspects of the invention;

FIG. 9B is a cross section taken along line A in FIG. 8, according to aspects of the invention;

FIG. 9C is a cross section taken along line C in FIG. 8, according to aspects of the invention;

FIG. 10 is a top view of the structure of FIGS. 8, and 9A-9C after angled ion implantation, according to aspects of the invention;

FIG. 11 is a cross section taken along line B in FIG. 10, according to aspects of the invention;

FIG. 12 is a top view of the structure of FIGS. 10, and 11A-11C after removal of some sacrificial SiGe, according to aspects of the invention;

FIG. 13A is a cross section taken along line B in FIG. 12, according to aspects of the invention;

FIG. 13B is a cross section taken along line A in FIG. 12, according to aspects of the invention;

FIG. 13C is a cross section taken along line C in FIG. 12, according to aspects of the invention;

FIG. 14 is a top view of the structure of FIGS. 12, and 13A-13C after deposition and etching of a unitary spacer structure, according to aspects of the invention;

FIG. 15A is a cross section taken along line B in FIG. 14, according to aspects of the invention;

FIG. 15B is a cross section taken along line A in FIG. 14, according to aspects of the invention;

FIG. 15C is a cross section taken along line C in FIG. 14, according to aspects of the invention;

FIG. 16 is a top view of the structure of FIGS. 14, and 15A-15C after etching for source-drain regions, according to aspects of the invention;

FIG. 17A is a cross section taken along line B in FIG. 16, according to aspects of the invention;

FIG. 17B is a cross section taken along line A in FIG. 16, according to aspects of the invention;

FIG. 17C is a cross section taken along line C in FIG. 16, according to aspects of the invention;

FIG. 18 is a top view of the structure of FIGS. 16, and 17A-17C after epitaxially growing source-drain regions, according to aspects of the invention;

FIG. 19A is a cross section taken along line B in FIG. 18, according to aspects of the invention;

FIG. 19B is a cross section taken along line A in FIG. 18, according to aspects of the invention;

FIG. 19C is a cross section taken along line C in FIG. 18, according to aspects of the invention;

FIG. 20 is a top view of the structure of FIGS. 18, and 19A-19C after depositing insulator and planarizing, according to aspects of the invention;

FIG. 21A is a cross section taken along line B in FIG. 20, according to aspects of the invention;

FIG. 21B is a cross section taken along line A in FIG. 20, according to aspects of the invention;

FIG. 21C is a cross section taken along line C in FIG. 20, according to aspects of the invention;

FIG. 22 is a top view of the structure of FIGS. 20, and 21A-21C after dummy gate removal, according to aspects of the invention;

FIG. 23A is a cross section taken along line B in FIG. 22, according to aspects of the invention;

FIG. 23B is a cross section taken along line A in FIG. 22, according to aspects of the invention;

FIG. 23C is a cross section taken along line C in FIG. 22, according to aspects of the invention;

FIG. 24 is a top view of the structure of FIGS. 22, and 23A-23C after etching those nanosheets not protected by hardmask in the channel region, according to aspects of the invention;

FIG. 25A is a cross section taken along line B in FIG. 24, according to aspects of the invention;

FIG. 25B is a cross section taken along line A in FIG. 24, according to aspects of the invention;

FIG. 25C is a cross section taken along line C in FIG. 24, according to aspects of the invention;

FIG. 26 is a top view of the structure of FIGS. 24, and 25A-25C after etching remaining sacrificial SiGe and round nanowires, according to aspects of the invention;

FIG. 27A is a cross section taken along line B in FIG. 26, according to aspects of the invention;

FIG. 27B is a cross section taken along line A in FIG. 26, according to aspects of the invention;

FIG. 27C is a cross section taken along line C in FIG. 26, according to aspects of the invention;

FIG. 28 is a top view of the structure of FIGS. 26, and 27A-27C after dummy gate removal and replacing with high-K metal gate, according to aspects of the invention;

FIG. 29A is a cross section taken along line B in FIG. 28, according to aspects of the invention;

FIG. 29B is a cross section taken along line A in FIG. 28, according to aspects of the invention;

FIG. 29C is a cross section taken along line C in FIG. 28, according to aspects of the invention; and

FIG. 30 shows a top view of an exemplary final structure, according to aspects of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

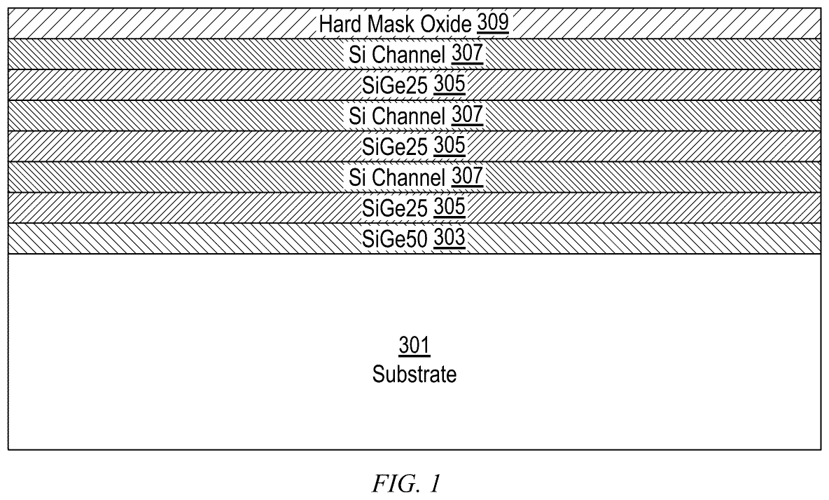

Aspects of invention provide techniques for multi-channel stack nanowire FETs and the like. FIG. 1 shows a starting structure in the fabrication of nanosheet field effect transistors, as will be familiar to the skilled artisan. A high SiGe layer 303 is located outward of a substrate 301. A plurality of alternating low SiGe sacrificial layers 305 and silicon channels 307 are located outward of the high SiGe layer. Hard mask 309 (e.g., oxide) is located outward of the outermost Si channel 307. In general, the high Ge % SiGe layer can include SiGe with the Ge % ranging from 40-75% (in one specific example, with the Ge %=50%); while the low Ge % SiGe layers can include SiGe with the Ge % ranging from 15-35% (in one specific example, with the Ge %=25%). “Low” and “high” % are definite as measured with respect to each other.

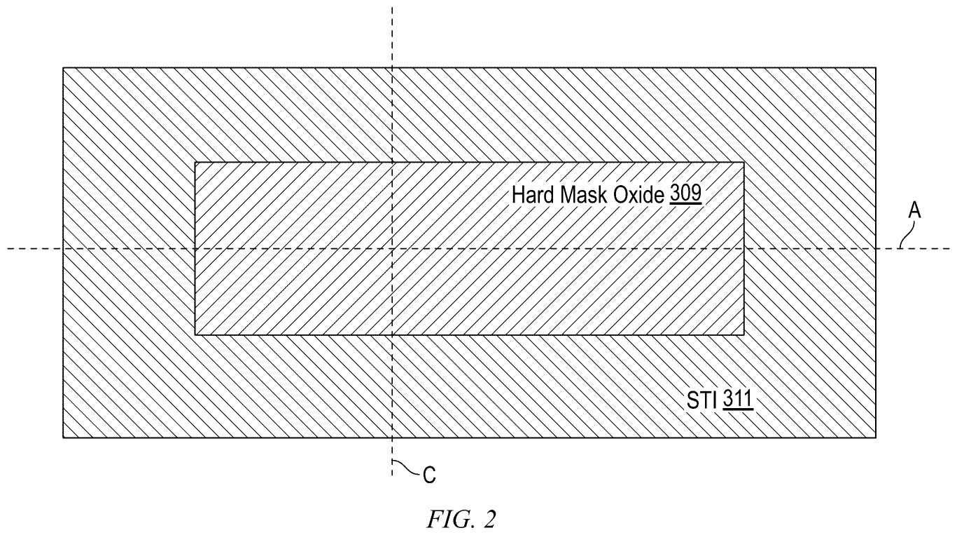

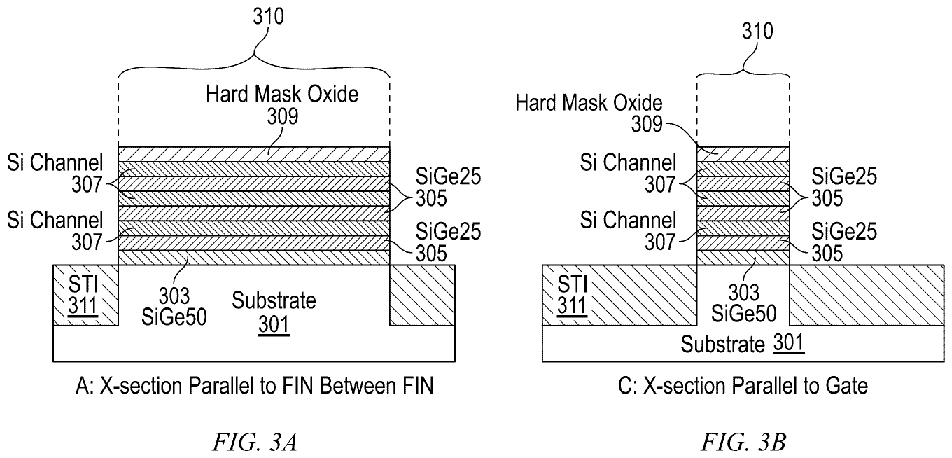

FIG. 2 shows a top view of the structure of FIG. 1 after patterning the hardmask and etching same to produce fins 310 (see FIGS. 3A and 3B), and depositing material for shallow trench isolation (STI) regions 311. Given the teachings herein, the skilled person can employ known techniques to carry out operations to obtain the structure of FIGS. 2 and 3A-3B from the starting structure. FIG. 3A is a cross section parallel to the fin between the fins taken along line A in FIG. 2. FIG. 3B is a cross section parallel to the gate taken along line C in FIG. 2.

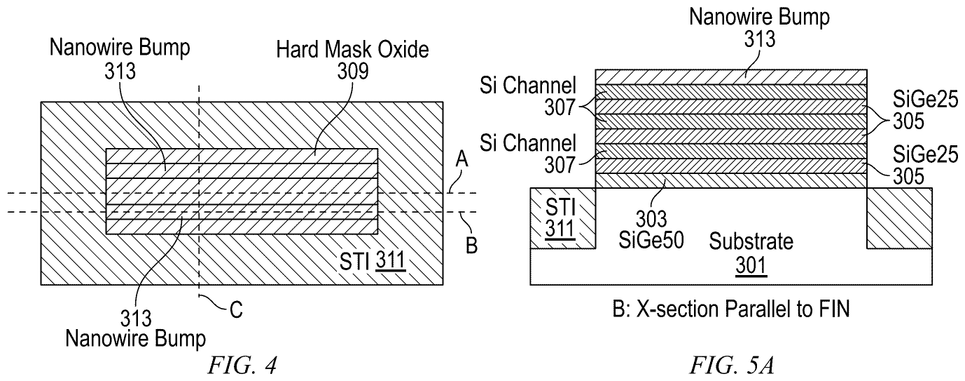

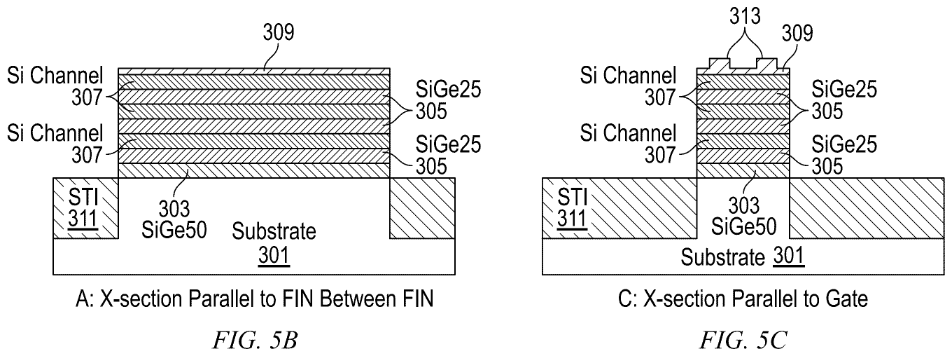

FIG. 4 shows a top view of the structure of FIGS. 2, 3A, and 3B after patterning the hard mask 309 to reduce the thickness thereof leaving nanowire bumps 313 that will later be used to pattern the Si channels 307 for nanowires. Given the teachings herein, the skilled person can employ known techniques, such as traditional lithography (EUV), SIT (side wall image transfer), or self-assembly, to carry out operations to obtain the structure of FIGS. 4 and 5A-5C from the preceding structure. FIG. 5A is a cross section parallel to the fin taken along line B in FIG. 4. FIG. 5B is a cross section parallel to the fin between the fins (note that at this stage, the nanowire is not released yet so reference is still made to fins) taken along line A in FIG. 4. FIG. 5C is a cross section parallel to the gate taken along line C in FIG. 4.

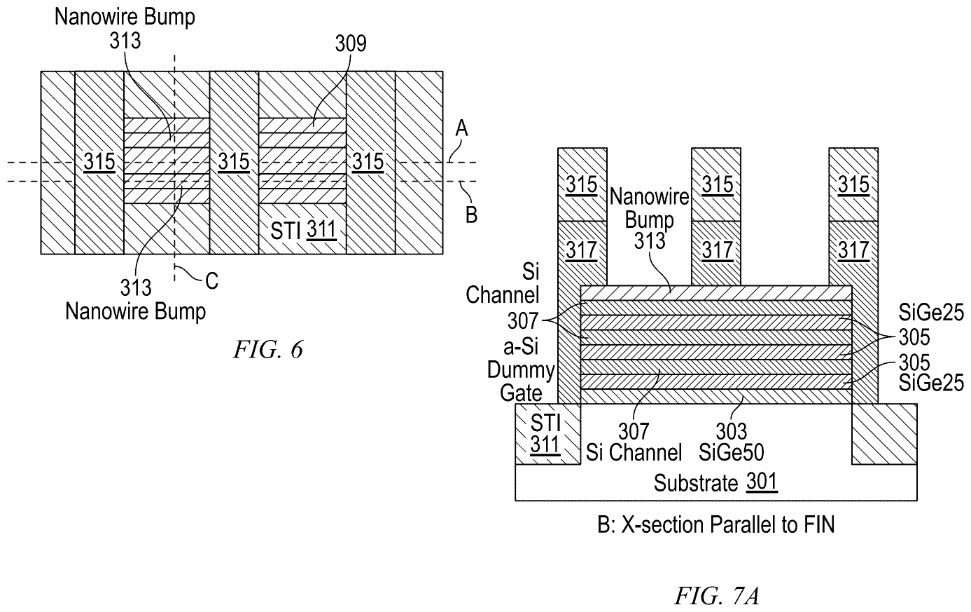

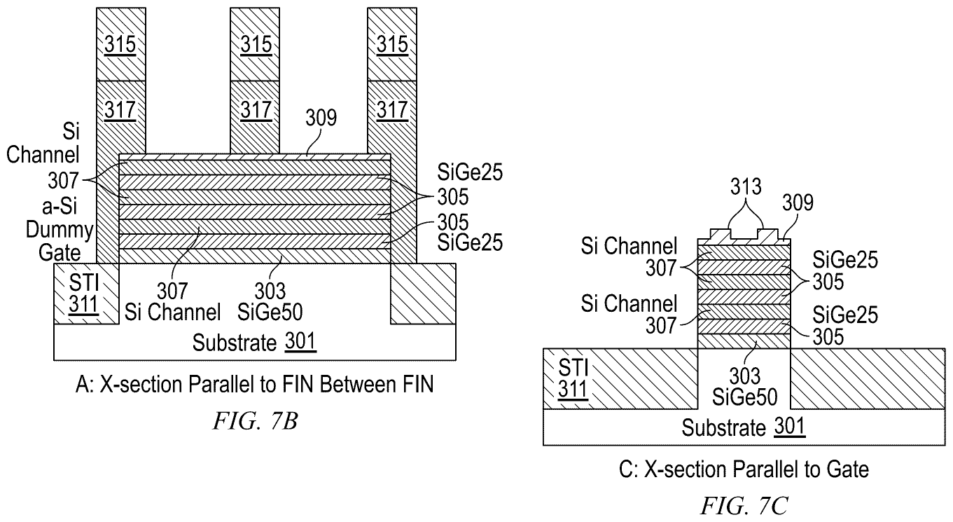

FIG. 6 shows a top view of the structure of FIGS. 4 and 5A-5C after patterning the dummy gates. Given the teachings herein, the skilled person can employ known techniques to carry out operations to obtain the structure of FIGS. 6 and 7A-7C from the preceding structure. Note the amorphous silicon (a-Si) dummy gates 317 with gate hard mask 315. FIG. 7A is a cross section parallel to the fin taken along line B in FIG. 6. FIG. 7B is a cross section parallel to the fin between the fins taken along line A in FIG. 6. FIG. 7C is a cross section parallel to the gate taken along line C in FIG. 6. The hard mask can be, for example, an oxide, a nitride, or a structure including a nitride and an oxide.

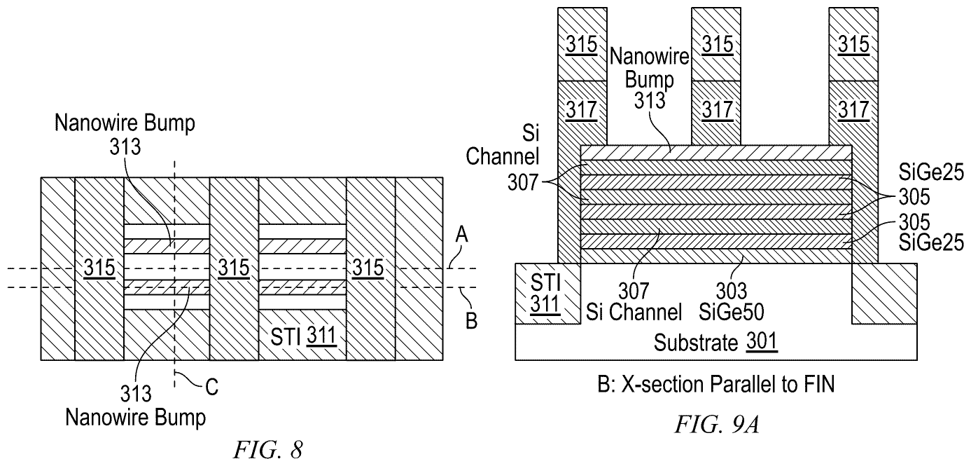

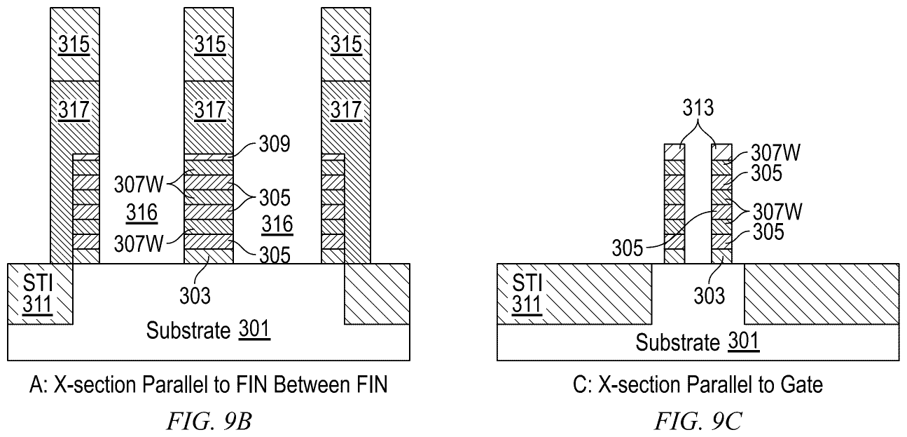

FIG. 8 shows a top view of the structure of FIGS. 6 and 7A-7C after etching through the fins to form cavities 316, seen in FIG. 9B. In one or more embodiments, etch the portions of the FIN region that are not covered by the hard mask. Given the teachings herein, the skilled person can employ known techniques to carry out operations to obtain the structure of FIGS. 8 and 9A-9C from the preceding structure. FIG. 9A is a cross section parallel to the fin taken along line B in FIG. 8. FIG. 9B is a cross section parallel to the fin between the fins taken along line A in FIG. 8. FIG. 9C is a cross section parallel to the gate taken along line C in FIG. 8. Comparing, for example, FIG. 9C to FIG. 7C, the Si channels 307 are etched into nanowires 307W where protected from the etchant by the nanowire bumps 313.

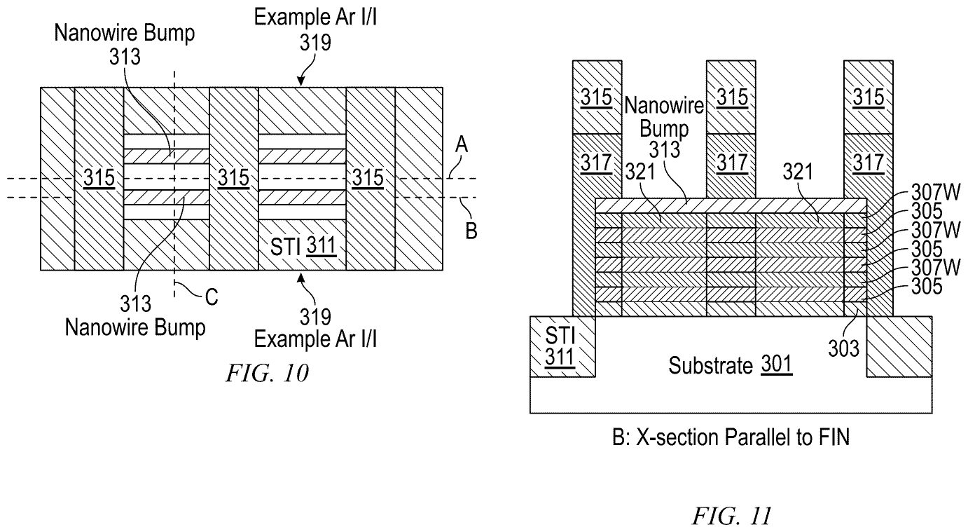

FIG. 10 shows a top view of the structure of FIGS. 8 and 9A-9C after angled ion implantation (I/I) (e.g., Argon ions) 319 to damage the sacrificial SiGe25 layers 305 so it will be easier to remove; the damaged regions are shown at 321 in FIG. 11, which is a cross section parallel to the fin taken along line B in FIG. 10.

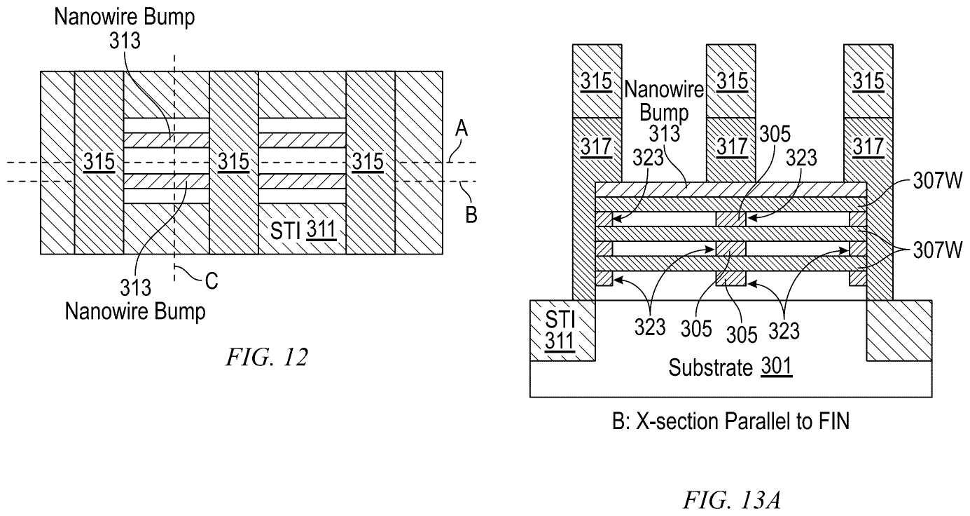

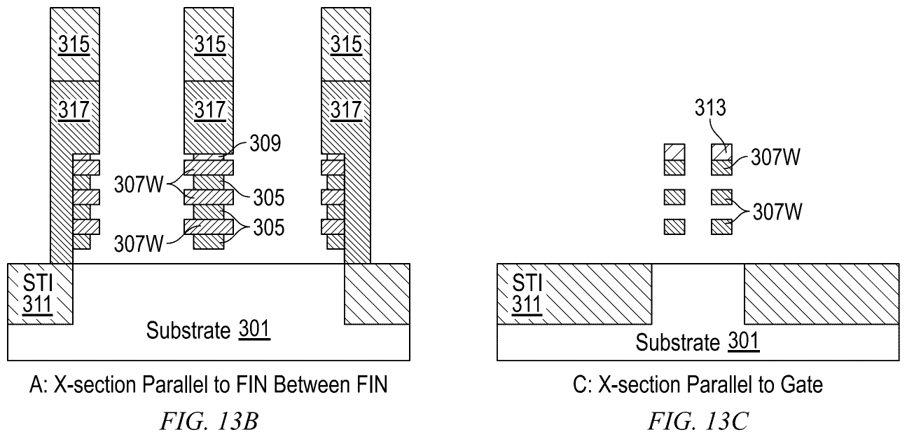

FIG. 12 shows a top view of the structure of FIGS. 10 and 11 after removing all of the SiGe50 (high SiGe layer) 303 and portions of the SiGe25 sacrificial layers 305 that have been damaged by the implantation. Given the teachings herein, the skilled person can employ known techniques (e.g., selective etching) to carry out operations to obtain the structure of FIGS. 12 and 13A-13C from the preceding structure. Note that some SiGe25 will be removed under the (dummy) gates 317, as seen at 323, which is desirable. FIG. 13A is a cross section parallel to the fin taken along line B in FIG. 12. FIG. 13B is a cross section parallel to the fin between the fins taken along line A in FIG. 12. FIG. 13C is a cross section parallel to the gate taken along line C in FIG. 12. FIG. 13C, the elements that appear to be “floating in the air” are retained by the dummy gates 317 as seen in FIG. 13B. In one or more embodiments, the SiGe50 is removed using gas HCl. The damaged SiGe25 (damaged from implantation) can also be removed selectively to undamaged SiGe25 using gas Phase HCl.

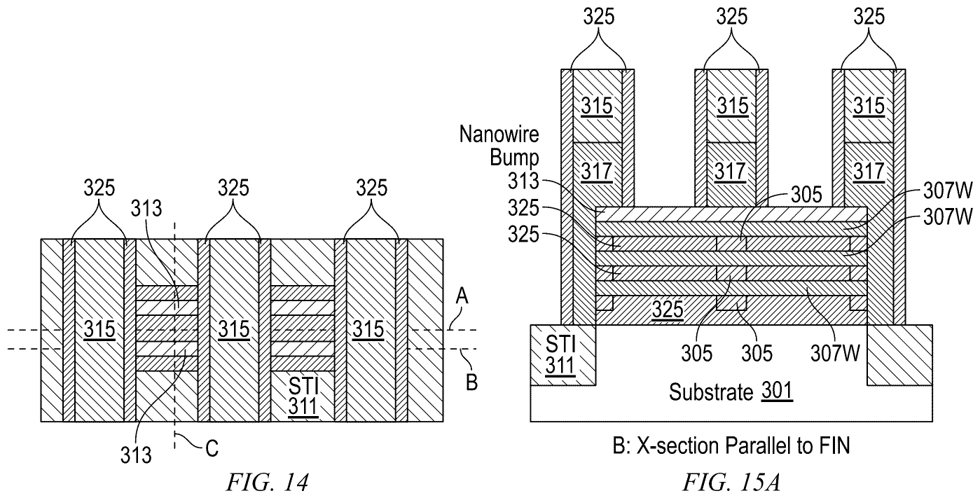

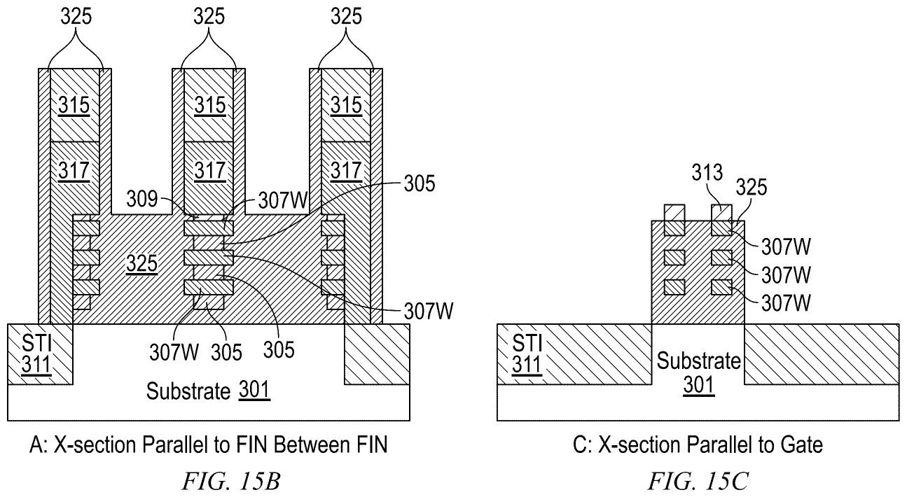

FIG. 14 shows a top view of the structure of FIGS. 12 and 13A-13C after depositing and etching a unified spacer structure 325 (which, as discussed elsewhere herein, takes the place of the separate gate spacers and inner spacers in the prior art). After the deposition and etching process the material of the unified spacer structure 325 covers the sides of the dummy gates and the regions vacated by the SiGe50 303 and SiGe25 layers 305. FIG. 15A is a cross section parallel to the fin taken along line B in FIG. 14. FIG. 15B is a cross section parallel to the fin between the fins taken along line A in FIG. 14. FIG. 15C is a cross section parallel to the gate taken along line C in FIG. 14. Conformal deposition is used in one or more embodiments. The same techniques can be used for forming NFETs, PFETs, or CMOS structures including both NFETs and PFETs.

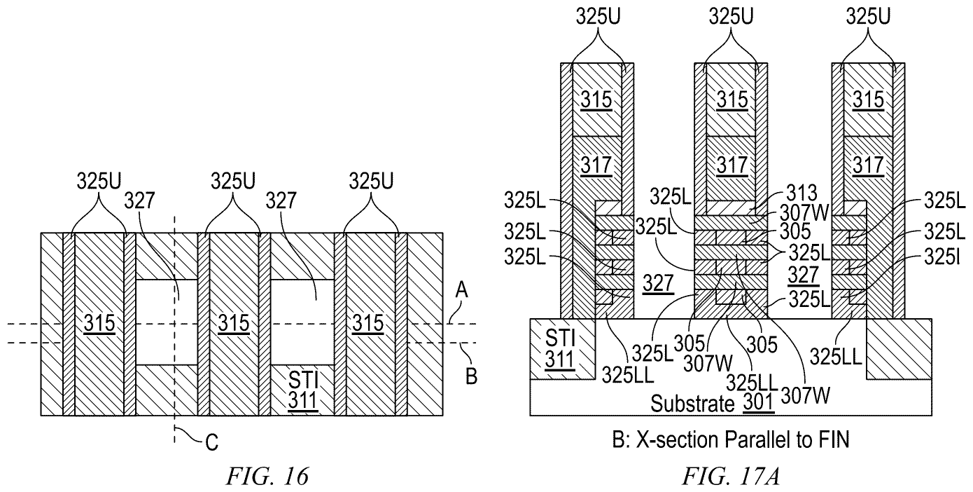

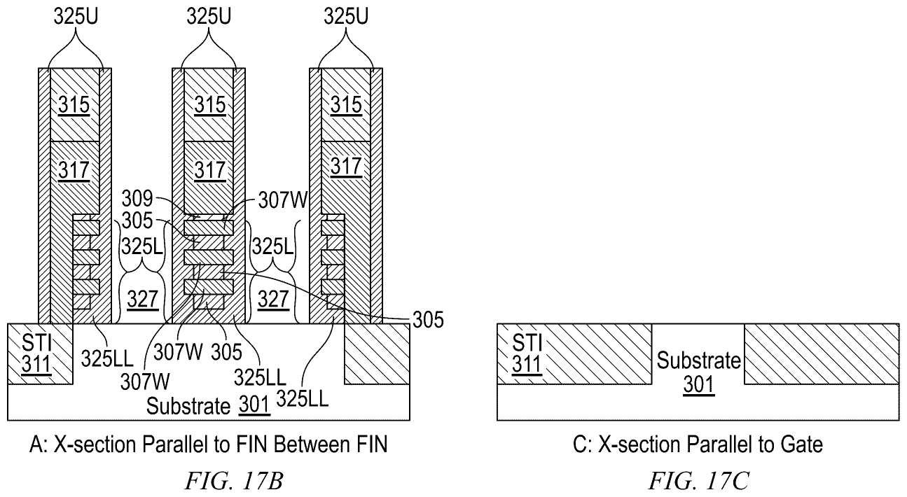

FIG. 16 shows a top view of the structure of FIGS. 14 and 15A-15C after etching openings 327 for the source-drain regions. FIG. 17A is a cross section parallel to the fin taken along line B in FIG. 16. FIG. 17B is a cross section parallel to the fin between the fins taken along line A in FIG. 16. FIG. 17C is a cross section parallel to the gate taken along line C in FIG. 16. At this stage, the unified spacer structure 325 of FIGS. 14 and 15A-15C includes upper spacer 325U; and lower spacer 325L with underlying portion 325LL. Upper spacer 325U has a similar function as the gate spacers in prior art structures, lower spacer 325L has a similar function as the inner spacers in prior art structures, and underlying portion 325LL of lower spacer 325L has a similar function as the bottom dielectric isolation (BDI) in prior art structures, but unlike in prior art methods, is deposited of uniform material in a single step. Given the teachings herein, the skilled person can employ known techniques to carry out operations to obtain the structure of FIGS. 16 and 17A-17C from the preceding structure.

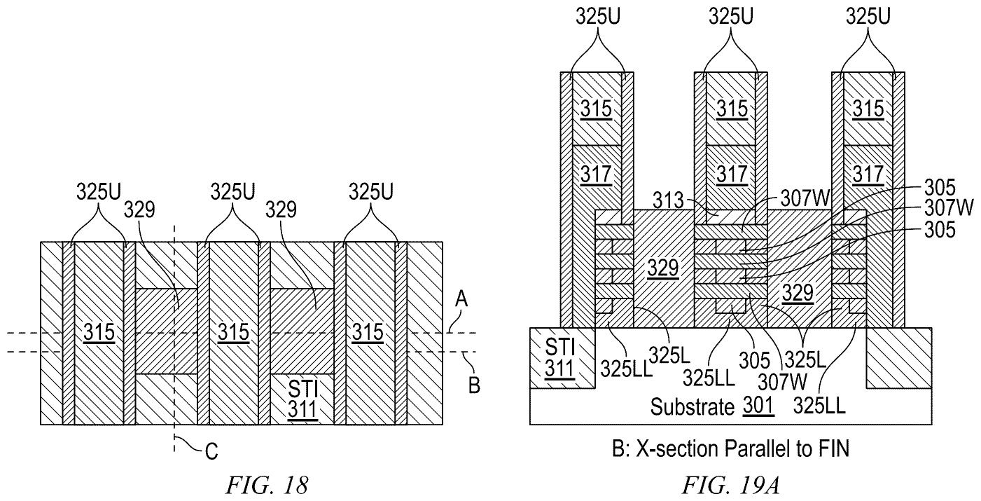

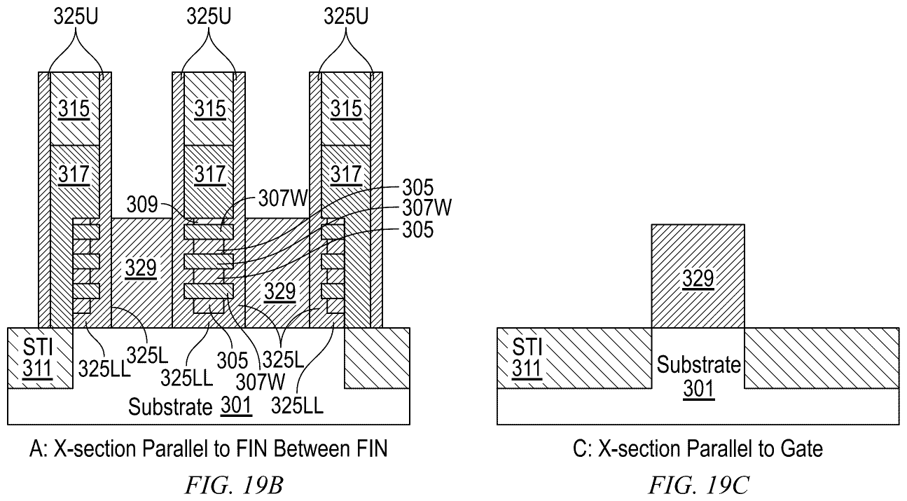

FIG. 18 shows a top view of the structure of FIGS. 16 and 17A-17C after growing source-drain epitaxy for first and second source/drain regions 329. FIG. 19A is a cross section parallel to the fin taken along line B in FIG. 18. FIG. 19B is a cross section parallel to the fin between the fins taken along line A in FIG. 18. FIG. 19C is a cross section parallel to the gate taken along line C in FIG. 18. Given the teachings herein, the skilled person can employ known techniques (epitaxial growth, doping) to carry out operations to obtain the structure of FIGS. 18 and 19A-19C from the preceding structure.

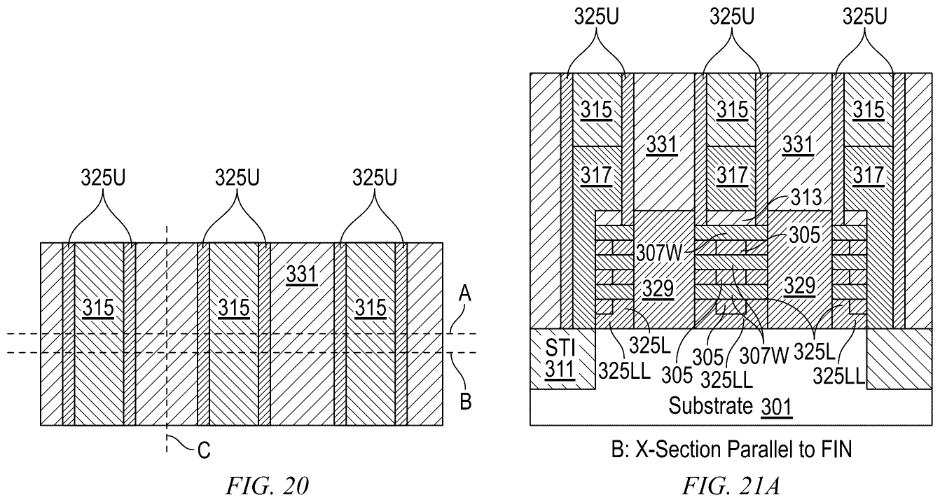

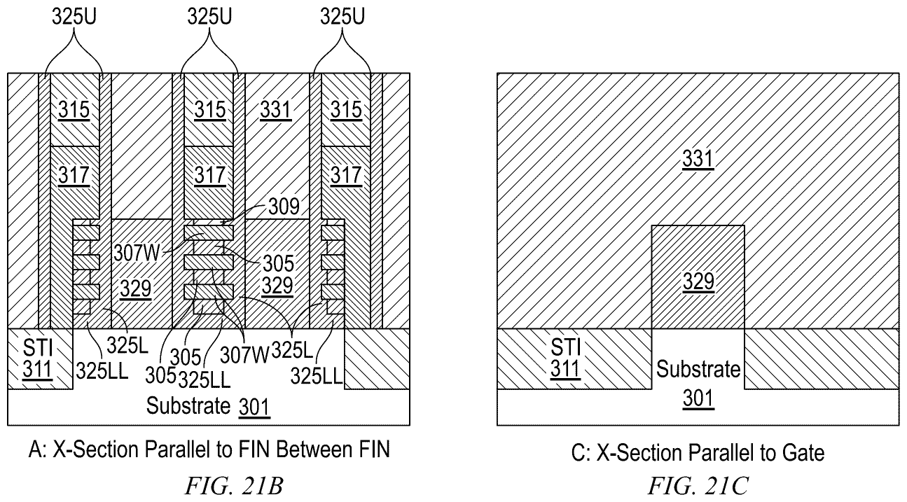

FIG. 20 shows a top view of the structure of FIGS. 18 and 19A-19C after depositing insulator 331 and planarizing. FIG. 21A is a cross section parallel to the fin taken along line B in FIG. 20. FIG. 21B is a cross section parallel to the fin between the fins taken along line A in FIG. 20. FIG. 21C is a cross section parallel to the gate taken along line C in FIG. 20. Given the teachings herein, the skilled person can employ known techniques (chemical-mechanical polishing or CMP) to carry out operations to obtain the structure of FIGS. 20 and 21A-21C from the preceding structure.

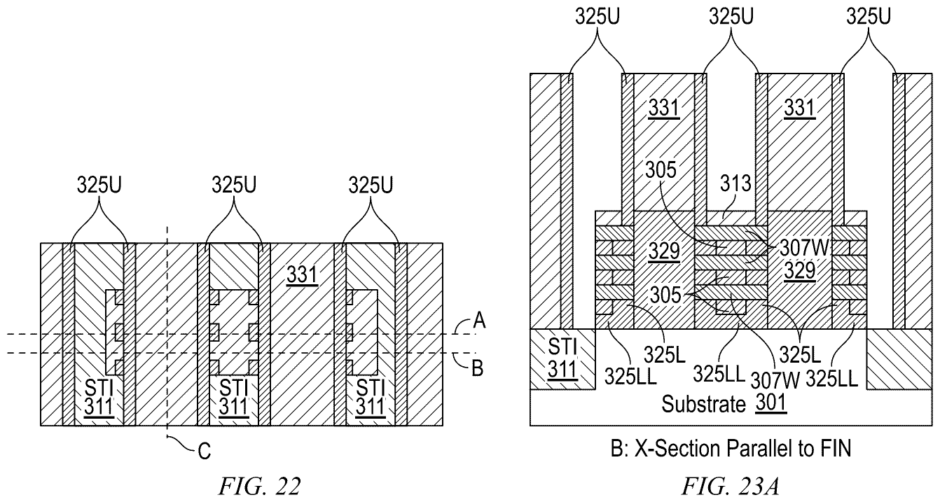

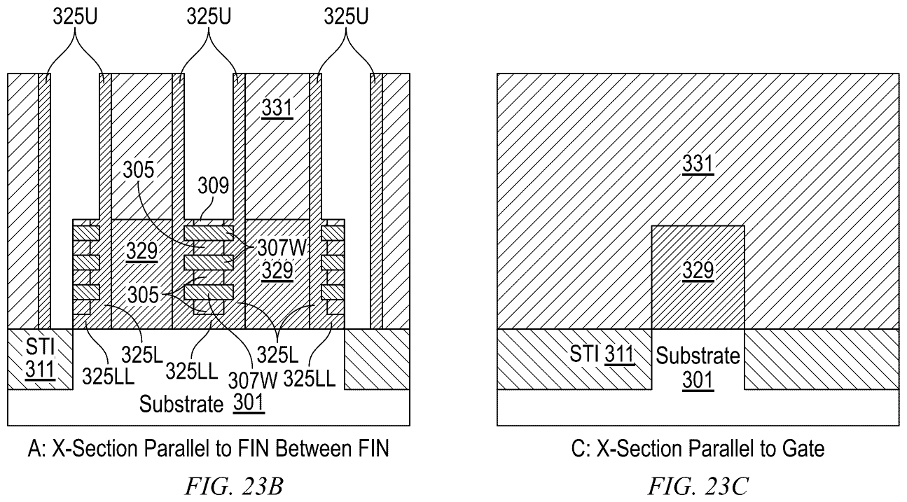

FIG. 22 shows a top view of the structure of FIGS. 20 and 21A-21C after dummy gate removal (i.e., removal of 315 and 317). FIG. 23A is a cross section parallel to the fin taken along line B in FIG. 22. FIG. 23B is a cross section parallel to the fin between the fins taken along line A in FIG. 22. FIG. 23C is a cross section parallel to the gate taken along line C in FIG. 22. Given the teachings herein, the skilled person can employ known techniques to carry out operations to obtain the structure of FIGS. 22 and 23A-23C from the preceding structure.

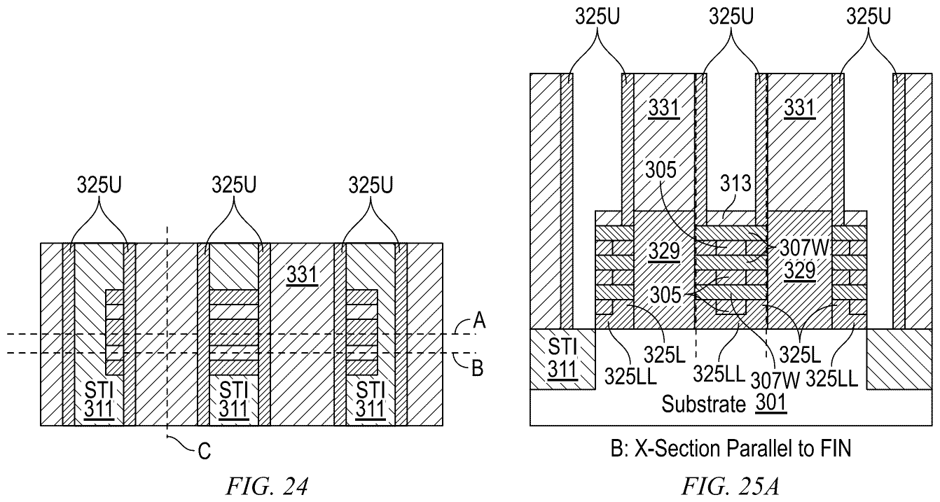

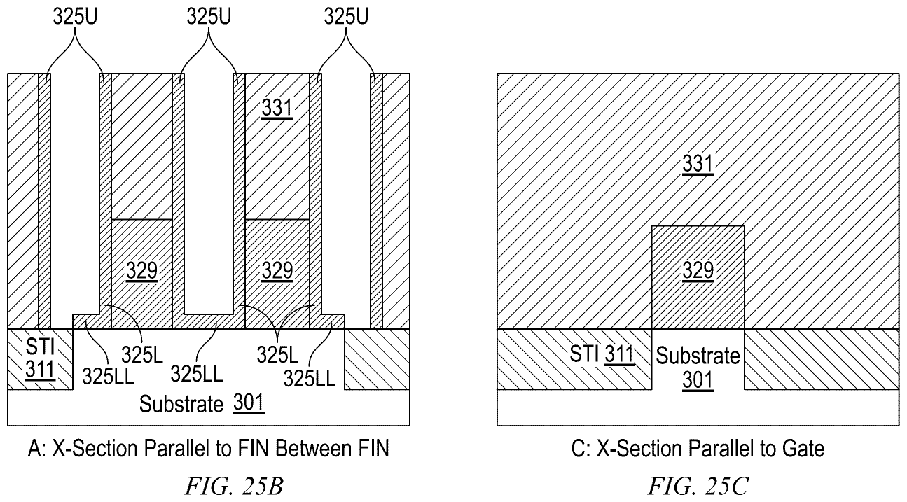

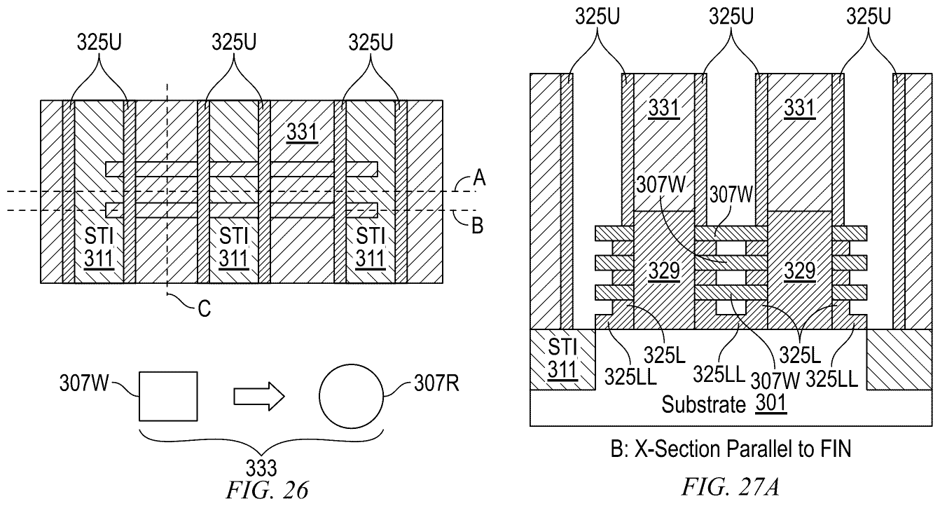

FIG. 24 shows a top view of the structure of FIGS. 22 and 23A-23C after etching those nanosheets not protected by nanowire bumps 313 which function as a thick hard mask in the channel region. FIG. 25A is a cross section parallel to the fin taken along line B in FIG. 24. FIG. 25B is a cross section parallel to the fin between the fins taken along line A in FIG. 24. FIG. 25C is a cross section parallel to the gate taken along line C in FIG. 24. Given the teachings herein, the skilled person can employ known techniques to carry out operations to obtain the structure of FIGS. 24 and 25A-25C from the preceding structure.

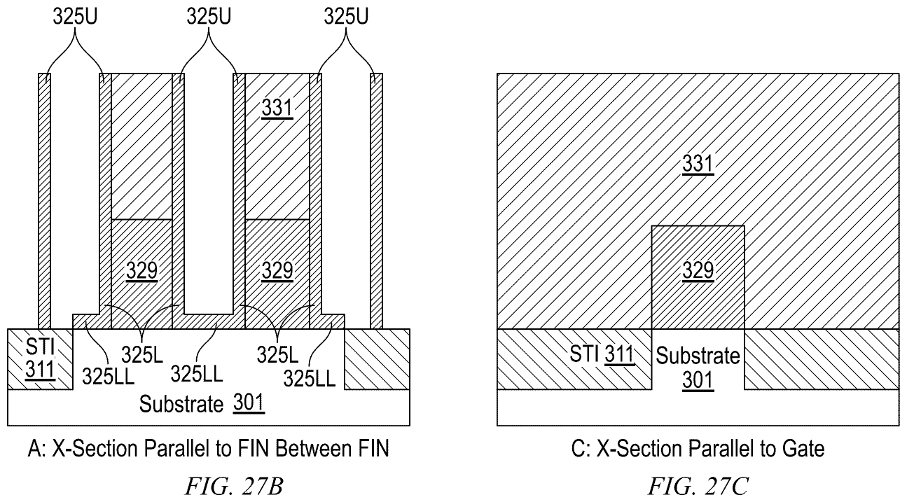

FIG. 26 shows a top view of the structure of FIGS. 24 and 25A-25C after etching the sacrificial SiGe layers 305 and rounding the nanowires 307W as seen at 333 (e.g., via etching or an oxidation method) to obtain rounded nanowires 307R. FIG. 27A is a cross section parallel to the fin taken along line B in FIG. 26. FIG. 27B is a cross section parallel to the fin between the fins taken along line A in FIG. 26. FIG. 27C is a cross section parallel to the gate taken along line C in FIG. 26. Given the teachings herein, the skilled person can employ known techniques to carry out operations to obtain the structure of FIGS. 26 and 27A-27C from the preceding structure.

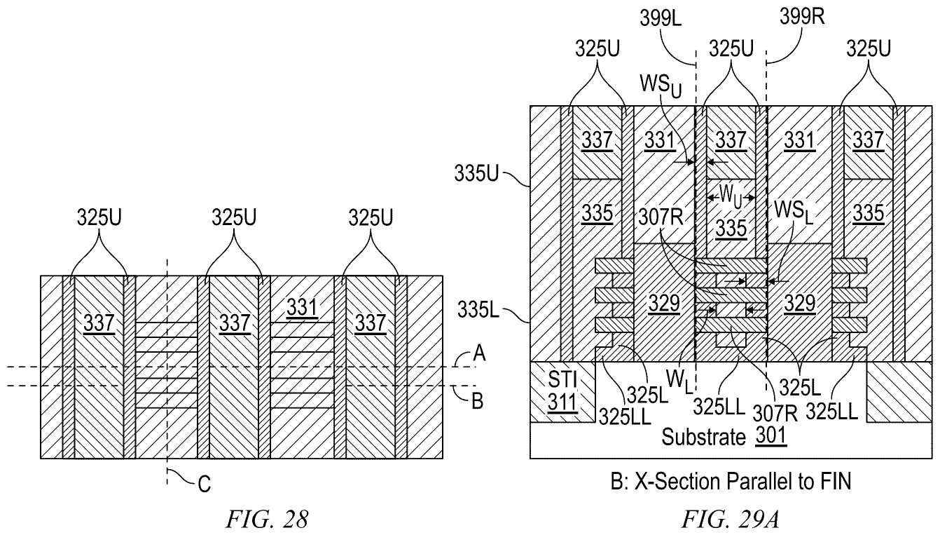

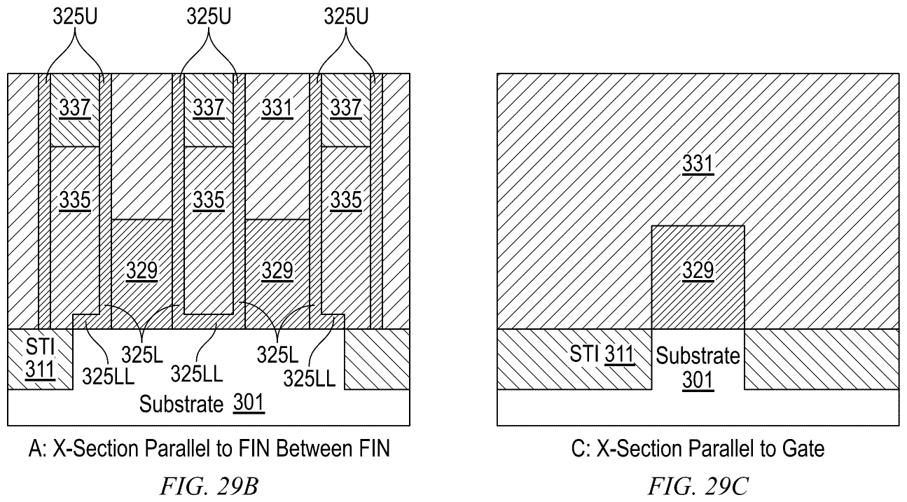

FIG. 28 shows a top view of the structure of FIGS. 26 and 27A-27C after removing the dummy gates as shown in FIGS. FIGS. 22 and 23A-23C and replacing same with high-K metal gate (HKMG) structures including metal 335 and High-K insulator 337. FIG. 29A is a cross section parallel to the fin taken along line B in FIG. 28. FIG. 29B is a cross section parallel to the fin between the fins taken along line A in FIG. 28. FIG. 29C is a cross section parallel to the gate taken along line C in FIG. 28. Given the teachings herein, the skilled person can employ known techniques to carry out operations to obtain the structure of FIGS. 28 and 29A-29C from the preceding structure.

After the step depicted in FIGS. 28 and 29A-29C, if it desired to form CMOS circuitry, the steps can be repeated for the other polarity (i.e., if NFETs were initially formed, the steps are repeated for PFETs or if NFETs were initially formed, the steps are repeated for PFETs). Processing then continues with known steps of contact formation and metallization. After the step depicted in FIGS. 28 and 29A-29C, if it is not desired to form CMOS circuitry (i.e., final structure to have FETs all of same type, whether NFETs or PFETs), processing continues with known steps of contact formation and metallization.

One or more embodiments accordingly provide closely spaced (e.g., 20-50 nm), rounded multi-channel stacked nanowires. One or more embodiments include defining nanosheets, defining nanowire hardmask, preparing dummy gates and spacers, epitaxially growing source-drain regions, etching the dummy gates, and etching the nanowires. Advantageously, one or more embodiments etch the nanowires after the dummy gate pull; use one unitary spacer structure 325, providing better scaling; and round the nanowires. Advantageously, one or more embodiments provide better short channel performance (reduce short channel effects), reduced parasitic capacitance, and greater scalability to smaller gate pitch values by using the single, unitary spacer.

Referring to FIGS. 28 and 29A-29C, one or more embodiments provide a nanostructure transistor including a common gate including metal 335 around a plurality of nanosheet channels (i.e., rounded nanowires 307R). As best seen in FIG. 29A, the common gate includes an upper gate portion 335U above the nanosheet channels and a lower gate portion 335L around the plurality of nanosheet channels. The width W_{U} of the upper gate portion 335U is wider than the width W_{L} of the lower portion 335L.

The nanostructure transistor further includes first and second source/drain regions 329 (i.e., one functions as a drain and the other as a source). The nanostructure transistor still further includes an upper spacer 325U between the upper gate portion and the source/drain region and a lower spacer 325L between the lower gate portion and the source/drain region. The width WS_{U} of the upper spacer is smaller than the width WS_{L} of the lower spacer, and the upper and lower spacers are separately labeled portions of a single, unitary spacer structure 325 simultaneously formed, unlike prior art. See, e.g., FIGS. 14-17C and accompanying text.

In an exemplary method of forming the just-described nanostructure transistor, the upper spacer and the lower spacer are simultaneously formed (i.e., there are no separate steps of forming spacer and inner spacer as in the prior art).

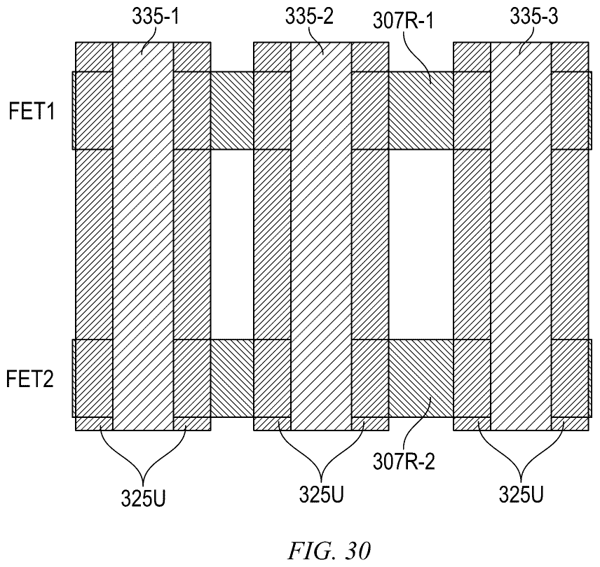

With continued reference to FIGS. 28 and 29A-29C, and with reference also now to FIG. 30, it will be appreciated that in one or more embodiments, a “final” structure includes a plurality of gate-all-around field effect transistors (e.g., FET1, FET2, . . . ) (as noted, further steps including metallization can be carried out; the structure is designated as “final” for convenience). Each of the gate-all-around field effect transistors includes first and second source-drain regions 329. A plurality of nanowire channels (rounded nanowires 307R) interconnect the first and second source-drain regions. A common gate (including gate metal 335) surrounds the plurality of nanowire channels. The common gate includes an upper gate portion 335U above the plurality of nanowire channels and a lower gate portion 335L surrounding the plurality of nanowire channels. The lower gate portion has a lower gate portion width W_{L}. The upper gate portion has an upper gate portion width W_{U} that is greater than the lower gate portion width.

A unitary spacer structure includes an upper spacer 325U between the upper gate portion 335U and the first and second source-drain regions 329 and a lower spacer 325L between the lower gate portion 335L and first and second source-drain regions 329. The lower spacer has a lower spacer width WS_{L}, and the upper spacer has an upper spacer width WS_{U} that is less than the lower spacer width.

Also note the substrate 301 with STI regions 311 inward of the transistors; the insulator 331; and the high-K insulator 337. Note further that the lower spacer 325L includes underlying portion 325LL between the lowermost portion of the lower gate portion 335L and the substrate 301. It is worth noting that in prior art structures, the BDI, inner spacers, and gate spacers are formed in separate steps and can even be of different materials, and do not form a unitary structure. Further, it is also worth noting that in prior art structures, in a cross-section view parallel to the fin, the gate (gate metal) has the same width in both upper and lower regions, and the gate spacers and inner spacers also have the same width.

FIG. 30 is a top view of a structure with multiple transistors FET1, FET2, . . . . Note the upper spacers 325U, three different high-K metal gate (HKMG) structures including metal 335-1, 335-2, 335-3 with the high-K insulator omitted from the view to permit “seeing” the gate metal. Note further the fins including stacks of nanowires designated as 307R-1 and 307R-2. The upper fin 307R-1 is for a first FET FET1 (e.g., an NFET or PFET) and the lower fin 307R-2 is for a second FET FET2 (e.g., a PFET or NFET). Note that the way the transistors are arranged can be, for example, NNPPNNPP, such that FET1 and FET2 can, in general, be N next to P, P next to N, P next to P, or N next to N. Some structure could be all P-type. Some structures could be all N-type. As noted elsewhere, if a CMOS structure is desired, the fabrication steps are repeated for the other type of epitaxy.

The skilled artisan will have general familiarity with techniques such as (dummy) gate opening (e.g., poly-opening chemical-mechanical polishing (POC) and polysilicon (dummy) gate pull), carrying out the replacement metal gate (RMG) process, middle of line (MOL) processing including contact formation, back end of line (BEOL) processing, bonding to a carrier wafer, SiGe release, high-K metal gate formation, deposition of interlayer dielectric (ILD), use of organic planarization layers (OPL), photolithography, formation of power and signal wiring, and the like.

Furthermore, given the teachings herein, for any elements for which example materials are not set forth, the skilled artisan can select appropriate materials, and for any fabrication steps for which specific exemplary processes have not been set forth, the skilled artisan can select appropriate known processes. Exemplary known processes, in no particular order, include, for example, preparation (deposition/patterning) of nanosheet stacks with sacrificial SiGe regions, etch-back of sacrificial SiGe, formation of shallow trench isolation (STI), dummy gates, dummy gate open, dummy gate removal, channel release, HKMG stack deposition, self-aligned contact (SAC) cap and trench metal contact formation, and with lithography, masks, and patterning, generally. The skilled artisan will be familiar with the “dummy gate” process for forming HKMGs. More generally, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term.

Bulk silicon is a non-limiting example of a suitable substrate material, other materials are also possible.

Given the discussion thus far, it will be appreciated that an exemplary semiconductor structure, according to aspects of the invention, includes a plurality of gate-all-around field effect transistors (e.g., FET1 and FET2 in FIG. 30). Each of the gate-all-around field effect transistors includes: first and second source-drain regions 329; a plurality of nanowire channels (rounded nanowires 307R) interconnecting the first and second source-drain regions; and a common gate including metal 335. The common gate includes an upper gate portion (e.g., with width of W_{U} in FIG. 29A) above the plurality of nanowire channels and a lower gate portion (e.g., with width of W_{L} in FIG. 29A) surrounding the plurality of nanowire channels. Also included is a unitary spacer structure including an upper spacer portion (see 325U) (e.g., with width WS_{U} in FIG. 29A) between the upper gate portion and the first and second source-drain regions and a lower spacer portion 325L (e.g., with width WS_{L} in FIG. 29A) between the lower gate portion and first and second source-drain regions. The upper spacer portion and the lower spacer portion have aligned left and right edges 399L and 399R as seen in FIG. 29A. In one or more embodiments, the left and right edges 399L and 399R are “perfectly” aligned in the sense that the left and right edges 399L and 399R will not have any detectable deviation from a straight line (no “kinks” in the line) when viewed in a transmission electron microscope (TEM) or scanning electron microscope (SEM) image.

In one or more embodiments, the lower gate portion has a lower gate portion width W_{L}; the upper gate portion has an upper gate portion width W_{U}; and the upper gate portion width is greater than the lower gate portion width.

In one or more embodiments, the lower spacer portion has a lower spacer width WS_{L}; the upper spacer portion has an upper spacer width WS_{U}; and the upper spacer width is less than the lower spacer width.

One or more embodiments further include a substrate 301; and a plurality of shallow trench isolation regions 311 in the substrate. The gate-all-around field effect transistors are formed on the substrate between the shallow trench isolation regions, as seen in FIG. 29A.

As seen in FIG. 26, in one or more embodiments, the nanowire channels are rounded in cross section.

One or more embodiments further include insulators 331 outward of the first and second source-drain regions 329.

In one or more embodiments, the lower spacer portion includes an underlying portion 325LL between the lower gate portion and the substrate.

In a non-limiting (CMOS) example, a first group of the plurality of gate-all-around field effect transistors are n-type and a second group of the plurality of gate-all-around field effect transistors are p-type.

In another aspect, another exemplary semiconductor structure includes a plurality of gate-all-around field effect transistors (e.g., FET1 and FET2 in FIG. 30). Each of the gate-all-around field effect transistors includes first and second source-drain regions 329; a plurality of nanowire channels (rounded nanowires 307R) interconnecting the first and second source-drain regions; and a common gate including metal 335. The common gate includes an upper gate portion above the plurality of nanowire channels and a lower gate portion surrounding the plurality of nanowire channels. The lower gate portion has a lower gate portion width W_{L}, and the upper gate portion has an upper gate portion width W_{U} greater than the lower gate portion width. Also included is a unitary spacer structure including an upper spacer 325U between the upper gate portion and the first and second source-drain regions and a lower spacer 325L between the lower gate portion and first and second source-drain regions. The lower spacer has a lower spacer width WS_{L}, and the upper spacer having an upper spacer width WS_{U} less than the lower spacer width.

One or more embodiments further include a substrate 301; and a plurality of shallow trench isolation regions 311 in the substrate; the gate-all-around field effect transistors are formed on the substrate between the shallow trench isolation regions (e.g., as seen in FIG. 29A).

As seen in FIG. 26, in one or more embodiments, the nanowire channels are rounded in cross section.

One or more embodiments further include insulators 331 outward of the first and second source-drain regions 329.

In one or more embodiments, the lower spacer portion 325L includes an underlying portion 325LL between the lower gate portion and the substrate 301.

In a non-limiting (CMOS) example, a first group of the plurality of gate-all-around field effect transistors are n-type and a second group of the plurality of gate-all-around field effect transistors are p-type.

In still another aspect, an exemplary method of forming a semiconductor structure includes providing a starting structure; e.g., as seen in FIGS. 8 and 9A-9C. The starting structure includes a substrate 301; the substrate has a plurality of shallow trench isolation regions 311 formed therein. The starting structure also has a plurality of fin stacks. Each of the fin stacks includes a high SiGe layer 303 located outward of the substrate 301, a plurality of alternating low SiGe sacrificial layers 305 and silicon channels 307 outward of the high SiGe layer, and hard mask oxide patterned into nanowire bumps 313 located outward of an outermost one of the silicon channels 307. The fin stacks have cavities 316 etched therein such that the silicon channels define nanowires with a generally square cross section. The starting structure further includes dummy gate stacks 315, 317 above the substrate and perpendicular to the fin stacks.

Referring, for example, to FIGS. 10 and 11A-11C, a further step includes carrying out angled ion implantation to damage the low SiGe sacrificial layers 305. Selective etching is carried out to remove all of the high SiGe layer 303 and parts of the alternating low SiGe sacrificial layers 305 damaged by the angled ion implantation; see FIGS. 12 and 13A-13C.

Referring, for example, to FIGS. 14 and 15A-15C, a still further step includes depositing (e.g., simultaneously) insulator material to form the unified spacer structure 325 between the dummy gate stacks and into the regions vacated by the removed high SiGe layer 303 and the removed part of the alternating low SiGe sacrificial layers 305, and etching the deposited insulator material to form a unified spacer structure covering sides of the dummy gate stacks and the regions vacated by the removed high SiGe layer and the removed part of the alternating low SiGe sacrificial layers.

Further steps include, as per FIGS. 18 and 19A-19C, epitaxially growing source-drain regions 329 between the gate stacks; and forming replacement metal gates 335 between the source-drain regions, to replace the dummy gate stacks (see FIGS. 28 and 29A-29C).

Referring, for example, to FIGS. 22 and 23A-23C, the dummy gate stacks are typically removed before forming the replacement metal gates. Referring to FIG. 26, one or more embodiments further include rounding the nanowires.

In one or more embodiments, the step of depositing and etching the insulator material includes forming the unified spacer structure to include an upper spacer portion (see 325U) between the dummy gate stacks and the first and second source-drain regions and a lower spacer portion 325L between remaining parts of the alternating low SiGe sacrificial layers and first and second source-drain regions. The lower spacer portion includes an underlying portion 325LL between an innermost one of the remaining parts of the alternating low SiGe sacrificial layers and the substrate.

In some instances, in the step of forming the replacement metal gates, the replacement metal gates 335 each include an upper gate portion above the plurality of nanowires and a lower gate portion surrounding the plurality of nanowires. The lower gate portion has a lower gate portion width W_{L}, the upper gate portion has an upper gate portion width W_{U}, and the upper gate portion width is greater than the lower gate portion width. In the step of depositing and etching the insulator material including forming the unified spacer structure, the lower spacer portion has a lower spacer width WS_{L}, the upper spacer portion has an upper spacer width WS_{U}; and the upper spacer width is less than the lower spacer width.

In some cases, the epitaxially grown source-drain regions are one of n-type and p-type, and the method further includes repeating the angled ion implantation, selective etching, depositing insulator material, epitaxially growth, and forming replacement metal gate steps for another one of n-type and p-type.

One or more embodiments further include depositing insulator 331 outward of the source-drain regions and planarizing a resulting structure.

As will be appreciated by the skilled artisan, since the spacer is a unitary spacer in one or more embodiments, the edges of the two spacers (left and right side of gates) are aligned.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. For example, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Those skilled in the art will appreciate that the exemplary structures discussed above can be distributed in raw form (i.e., a single wafer having multiple unpackaged chips), as bare dies, in packaged form, or incorporated as parts of intermediate products or end products.

An integrated circuit in accordance with aspects of the present inventions can be employed in essentially any application and/or electronic system. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A semiconductor structure comprising:
a plurality of gate-all-around field effect transistors, each of the gate-all-around field effect transistors including:
first and second source-drain regions;
a plurality of nanowire channels interconnecting the first and second source-drain regions;
a common gate, the common gate including an upper gate portion above the plurality of nanowire channels and a lower gate portion surrounding the plurality of nanowire channels; and
a unitary spacer structure including an upper spacer portion between the upper gate portion and the first and second source-drain regions and a lower spacer portion between the lower gate portion and the first and second source-drain regions, the upper spacer portion and the lower spacer portion having aligned left and right edges.

2. The semiconductor structure of claim 1, wherein;
the lower gate portion has a lower gate portion width;
the upper gate portion has an upper gate portion width; and
the upper gate portion width is greater than the lower gate portion width.

3. The semiconductor structure of claim 2, wherein:
the lower spacer portion has a lower spacer width;
the upper spacer portion has an upper spacer width; and
the upper spacer width is less than the lower spacer width.

4. The semiconductor structure of claim 3, further comprising:
a substrate; and
a plurality of shallow trench isolation regions in the substrate;
wherein the gate-all-around field effect transistors are formed on the substrate between the shallow trench isolation regions.

5. The semiconductor structure of claim 4, wherein the nanowire channels are rounded in cross section.

6. The semiconductor structure of claim 5, further comprising insulators outward of the first and second source-drain regions.

7. The semiconductor structure of claim 6, wherein the lower spacer portion includes an underlying portion between the lower gate portion and the substrate.

8. The semiconductor structure of claim 7, wherein a first group of the plurality of gate-all-around field effect transistors are n-type and a second group of the plurality of gate-all-around field effect transistors are p-type.

9. A method of forming a semiconductor structure, comprising:
providing a starting structure comprising:
a substrate, the substrate having a plurality of shallow trench isolation regions formed therein;
a plurality of fin stacks, each of the fin stacks including a high SiGe layer located outward of the substrate, a plurality of alternating low SiGe sacrificial layers and silicon channels outward of the high SiGe layer, and hard mask oxide patterned into nanowire bumps located outward of an outermost one of the silicon channels, the fin stacks having cavities etched therein such that the silicon channels define nanowires with a generally square cross section; and
dummy gate stacks above the substrate and perpendicular to the fin stacks;
carrying out angled ion implantation to damage the low SiGe sacrificial layers;
carrying out selective etching to remove all high SiGe layer and part of the alternating low SiGe sacrificial layers damaged by the angled ion implantation;
depositing insulator material between the dummy gate stacks and into the regions vacated by the removed high SiGe layer and removed part of the alternating low SiGe sacrificial layers, and etching the deposited insulator material to form a unified spacer structure covering sides of the dummy gate stacks and the regions vacated by the removed high SiGe layer and the removed part of the alternating low SiGe sacrificial layers;
epitaxially growing source-drain regions between the gate stacks; and
forming replacement metal gates between the source-drain regions, to replace the dummy gate stacks.

10. The method of claim 9, further comprising:
removing the dummy gate stacks; and
rounding the nanowires.

11. The method of claim 10, wherein the step of depositing and etching the insulator material includes forming the unified spacer structure to include an upper spacer portion between the dummy gate stacks and the first and second source-drain regions and a lower spacer portion between remaining parts of the alternating low SiGe sacrificial layers and first and second source-drain regions, wherein the lower spacer portion includes an underlying portion between an innermost one of the remaining parts of the alternating low SiGe sacrificial layers and the substrate.

12. The method of claim 11, wherein:
in the step of forming the replacement metal gates, the replacement metal gates each include an upper gate portion above the nanowires and a lower gate portion surrounding the plurality of nanowires, the lower gate portion has a lower gate portion width, the upper gate portion has an upper gate portion width, and the upper gate portion width is greater than the lower gate portion width; and
in the step of depositing and etching the insulator material including forming the unified spacer structure, the lower spacer portion has a lower spacer width, the upper spacer portion has an upper spacer width; and the upper spacer width is less than the lower spacer width.

13. The method of claim 9, wherein the source-drain regions are one of n-type and p-type, further comprising repeating the angled ion implantation, selective etching, depositing insulator material, epitaxially growth, and forming replacement metal gate steps for another one of n-type and p-type.

14. The method of claim 9, further comprising depositing insulator outward of the source-drain regions and planarizing a resulting structure.

15. A semiconductor structure comprising:
a plurality of gate-all-around field effect transistors, each of the gate-all-around field effect transistors including:
first and second source-drain regions;
a plurality of nanowire channels interconnecting the first and second source-drain regions;
a common gate, the common gate including an upper gate portion above the plurality of nanowire channels and a lower gate portion surrounding the plurality of nanowire channels, the lower gate portion having a lower gate portion width, the upper gate portion having an upper gate portion width greater than the lower gate portion width; and
a unitary spacer structure including an upper spacer between the upper gate portion and the first and second source-drain regions and a lower spacer between the lower gate portion and the first and second source-drain regions, the lower spacer having a lower spacer width, the upper spacer having an upper spacer width less than the lower spacer width.

16. The semiconductor structure of claim 15, further comprising:
a substrate; and
a plurality of shallow trench isolation regions in the substrate;
wherein the gate-all-around field effect transistors are formed on the substrate between the shallow trench isolation regions.

17. The semiconductor structure of claim 16, wherein the nanowire channels are rounded in cross section.

18. The semiconductor structure of claim 17, further comprising insulators outward of the first and second source-drain regions.

19. The semiconductor structure of claim 18, wherein the lower spacer includes an underlying portion between the lower gate portion and the substrate.

20. The semiconductor structure of claim 19, wherein a first group of the plurality of gate-all-around field effect transistors are n-type and a second group of the plurality of gate-all-around field effect transistors are p-type.
